(19) United States
(12) Patent Application Publication
(10) Pub. No.: US 2017/0098748 A1
(43) Pub. Date: Apr. 6, 2017

(54) Thermo-electric device to provide electrical power

(71) Applicant: Karl Joseph Steutermann, Crestwood, KY (US)

(72) Inventor: Karl Joseph Steutermann, Crestwood, KY (US)

(21) Appl. No.: 14/999,538

(22) Filed: May 21, 2016

Related U.S. Application Data
(60) Provisional application No. 62/164,973, filed on May 21, 2015.

(51) Int. Cl. H01L 35/02; H01L 35/28

(52) U.S. Cl. CPC H01L 35/02; H01L 35/28

(57) ABSTRACT

A thermoelectric device to generate electrical power at relatively high voltages using a thermopile, temperature differentials regarding the thermopile and the Seebeck Coefficient of dissimilar materials assembled in a unique manner and in conjunction with controls and batteries to power devices such as electric motors used in electric cars and emergency backup situations, for example.

### CROSS REFERENCE TO RELATED APPLICATIONS

This application claims priority from U.S. Provisional Patent Application Ser. No. 62/164,937 filed on May 21, 2015 which is incorporated by reference herein in it's entirety.

### TECHNICAL FIELD

A thermoelectric device to generate electrical power at relatively high voltages using a thermopile.

### BACKGROUND OF THE INVENTION

The present invention relates to the field of devices used to generate power for electrical powered devices and back-up power for large motors and other emergency electrical power needs, in the event of a power failure.

Electric cars use many expensive and heavy batteries with a limited capacity, in other words, miles per charge. Recharge stations for these vehicles have specialized chargers for the different types of batteries. These stations are expensive and require maintenance.

Many industrial, commercial and residential entities such as hospitals, factories, banks, commercial retailers, and so on require back-up power in case of power loss due to storms, accidents or other power failure. Hospitals require back-up power in the case of power loss. Data loss in banking and commercial enterprises can cost thousands of dollars or more. Many such entities have dedicated back-up generators which automatically fire up to maintain power. Such generators are gas or diesel powered devices. Computer and data back-up are often in the form of large banks of DC batteries. Uninterruptible Power Supplies or (UPS's) provide back-up power for many computer systems. In addition, space and remote habitat facilities require electrical power in isolated environments.

Creation and use of electrical power for sustained periods of time without use of fuels and without connection to the electrical grid is severely restricted. Radioisotope thermoelectric generators, (“RTG”), are electric generators that use an array of thermocouples to convert the heat released by the decay of a suitable radioactive material into electricity. The instant invention solves this problem of generation of electrical power without the use of fuels and without the use of radioactive material.

### SUMMARY OF THE INVENTION

In accordance with the present invention, there is provided an electrical power generation system comprising, consisting of, or consisting essentially of a liquid nitrogen generating and storage system connected to a control circuit through high current switching transistors. A large thermopile having a temperature gradient generated between the liquid nitrogen and ambient air temperature gradient causes the thermopile to generate a large DC voltage at two output terminals supplying a DC voltage to the control circuit. A group of rechargeable batteries is connected to the control circuit through high current switching transistors. A parallel grouping of large power capacitors capable of operating in a range of hundreds of volts DC is connected to the control circuit through high current switching transistors. The control circuit includes high current switching transistors capable of switching large currents in a range of hundreds of amps at voltages in a range of hundreds of volts. The circuit connects the batteries to the grouping of capacitors through selected switching transistors. The circuit connects the thermopile to the grouping of capacitors through selected switching transistors and the circuit connects a winding of a motor to the grouping of capacitors through selected switching transistors by either of two possible polarities providing the positive and negative half cycles of a quasi sinusoidal power signal.

The present invention utilizes thermocouples aligned in a series to comprise a thermopile and includes a coolant, electrical capacitance means, rechargeable batteries and means of witching output power to the capacitance means between the thermocouples and means of electrical power storage.

The batteries are used to charge the capacitance means. The Switching Unit (hereafter SU) disconnects the batteries from the capacitance means. The SU then connects thermopile to capacitance means in series. The capacitance means is then discharged through an electrically powered device at the voltage of the thermopile. The process is repeated roughly 60 or more time per second.

The present invention is a thermoelectric device which generates relatively high voltages, between 110V and 900V or more using a thermopile, temperature differentials and the Seebeck Coefficient of dissimilar materials assembled in a unique manner and in conjunction with controls and batteries to power devices such as an electric motor.

Cold liquid is passed over the junction ends of the thermopile creating a large potential difference. The Switching Unit (hereafter SU) switches circuit to one of charging the capacitance means from the batteries, to a circuit isolating the capacitance means, to a circuit connecting the capacitance means in series after the thermopile, to a circuit with the thermopile and capacitance means in series with an electrical device such as an electric motor. Thus the capacitor is discharged at the high voltage of the thermopile creating high power for the electrically powered device such as an electric motor. The switching is conducted at high frequencies such as 60 Hz and greater to create a quasi-continuous power source. Solid State Power Transistors are used to switch the circuitry in cycles. The state (1) in the cycle is to switch the circuitry to one of charging the capacitance means with a battery source. State (2), the switches then open all gates and disengage from the battery circuit and isolate the capacitance means from any other circuitry. State (3) the switches then close gates necessary to create a circuit where the capacitance means is second in series with a large voltage thermopile. State (4), the switches then close a gate whereas the capacitance means discharges through to the power input of an electrically powered device. The switches then activate to close and open gates such that the circuitry returns to state (1).

Solid State Power Transistors are used to switch the circuitry in cycles using a variable timing/pulse circuit. The state (1) in the cycle is to switch the circuitry to one of charging the capacitance means with a battery source. State (2), the switches then open all gates and disengage from the battery circuit and isolate the capacitance means from any other circuitry. State (3) the switches then close gates necessary to create a circuit where the capacitance means is second in series with a large voltage thermopile. State (4), the switches then close a gate whereas the capacitance means discharges through to the power input of an electrically powered device. The switches then activate to close and open gates such that the circuitry returns to state (1).

The thermopile is constructed of two materials with relatively high and compatible Seeback Coefficient properties. The materials are clad to a high dielectric substrate and thermocouple lines are etched or printed onto the substrate as would occur in common printing of a circuit board. Thus many thermocouples can be created in a small space. The printed thermopile on a dielectric, called a thermopile card, is then wired in series with other thermopile cards to create a very large single thermopile. Low temperature coolant, such as liquid nitrogen, is passed over the junction ends of the thermopile with the other ends exposed to atmospheric or higher temperatures. Thus a large voltage potential is created. A low temperature pump will flow coolant to the thermopile from a temperature insulated reservoir. The switching unit will consist of a printed circuit board with power transistors and timing circuit of standard design and manufacturing methods. The timing circuit will activate transistors in a specific order and frequency. Solid state power transistors are used to switch the circuitry in cycles. The state (1) in the cycle is to switch the circuitry to one of charging the capacitance means with a battery source. State (2), the switches then open all gates and disengage from the battery circuit and isolate the capacitance means from any other circuitry. State (3) the switches then close gates necessary to create a circuit where the capacitance means is second in series with a large voltage thermopile. State (4), the switches then close a gate whereas the capacitance means discharges through to the power input of an electrically powered device. The switches then activate to close and open gates such that the circuitry returns to state (1).

The coolant reservoir should be made of high thermal conductive resistance to maintain the low temperature of the fluid. The batteries used in the design can be rechargeable.

The present invention includes the generation and storage of liquid nitrogen. Then, in the event of a power failure, the liquid nitrogen is used to generate a large temperature gradient for a large bank of thermopiles which in turn generate DC voltage and current which is then converted to AC voltage to drive motors and other critical loads.

It is an object of this invention to provide a power generator for powering electric vehicles and equipment using liquid nitrogen and air to provide a temperature gradient which enables a thermopile to supply high DC voltage and to use the DC voltage in combination with capacitors charged by onboard batteries and control circuitry is used to power an electric vehicle or other device.

It is an object of this invention to provide a thermo-electric power generator capable of powering motors or other electrical loads in the range of tens or hundreds of horsepower.

It is an object of this invention to provide a thermo-electric power generator capable of generating single phase or three phase power.

It is an object of the present invention to provide creates useful quantities of electric power by generating thermo electricity to assist and extend the life of batteries.

It is an object of the present invention to provide a device which uses coolant to create a temperature differential which is used to develop thermo-electricity from multiple thermocouples in series providing a quantity of electricity exceeding 750 watts.

It is an object to provide a thermoelectric device to generate electrical power at relatively high voltages, between 110V and 900V or more using a thermopile.

It is an object of this invention to provide a thermo-electric power generator having a plurality of thermo-piles which are cooled by liquid nitrogen. The liquid nitrogen can also be generated and stored by the power generator while in an idle (that is a non-power generating) state.

It is an object of this invention to provide a thermo-electric power generator which includes rechargeable batteries which are recharged by input power from the utility company, and to provide power from the battery and liquid nitrogen cooled thermopiles to generate back-up electricity to the generator.

It is an object of this invention to provide a means for generating electrical power for sustained periods of time without use of fuels and without connection to the electrical grid is unattainable.

It is an object of this invention to provide a system to generate electricity that is useful in powering mechanical devices or devices requiring in excess of 750 watts.

It is an object of this invention to provide a device creating large quantities of electrical power without the use of fuels and can be portable.

Other objects, features, and advantages of the invention will be apparent with the following detailed description taken in conjunction with the accompanying drawings showing a preferred embodiment of the invention.

### BRIEF DESCRIPTION OF THE DRAWINGS

A better understanding of the present invention will be had upon reference to the following description in conjunction with the accompanying drawings in which like numerals refer to like parts throughout the views wherein:

FIG. 1 is a front view of a zig-zag arrangement of nichrome wire;

FIG. 2 is a front view of the nichrome wire of FIG. 1 with a insulating card covering the mid-section of the zig-zag pattern;

FIG. 3 is a front view of the nichrome wire and insulating card of FIG. 2 with another zig-zag arrangement of constantan wire over-laying the insulating card with upper and lower loops of the two wires touching, the combination constituting a thermopile card;

FIG. 4 is a front view of the wire and card arrangement of FIG. 3 with an additional insulating card covering the constantan wire;

FIG. 5 is an edge view of the wire and card arrangement of FIG. 3 with an additional insulating card covering the constantan wire;

FIG. 6 is another edge view of the wire and card arrangement of FIG. 3 with an additional insulating card covering the constantan wire;

FIG. 7 is a front view of a circular arrangement of thermopile cards on end with one edge with joined leads of the cards facing to the center of the circle and the other edge of the opposite joined leads of cards facing toward the outside of the circle;

FIG. 8 is an upper front view of a plurality of thermopile cards arranged parallel to one another;

FIG. 9 is an upper front view of two arrangements of the thermopile cards of FIG. 9;

FIG. 10 is a diagram a pressure swing absorption system;

FIG. 11 is a diagram of a Peltier cooling bath system;

FIG. 12 is a diagram of a liquid nitrogen containment system;

FIG. 13 is a diagram showing the cryogenic system combination of the nitrogen generator pressure swing absorption system of FIG. 10, the cooling bath system of FIG. 11, and the liquified nitrogen containment vessel cooler and condenser shown in FIG. 12 used to supply the liquid nitrogen cooling fluid to the thermopile;

FIG. 14 is a front view of a nitrogen separator;

FIG. 15 is a diagram showing the cryogenic system combining a nitrogen generator as shown in FIG. 14, a cooling bath system as shown in FIG. 11, and a liquified nitrogen containment vessel as shown in FIG. 12 used to supply the liquid nitrogen cooling fluid to the thermopile;

FIG. 16 shows a plurality of thermocouples configured as a simple thermopile;

FIG. 17 shows control circuit 1 cycle for the electrical power generation system showing the electrical circuit including the batteries, capacitors, thermopile and switches connected to power a motor;

FIG. 18 shows control circuit 2 cycle for the electrical power generation system showing the electrical circuit including the batteries, capacitors, thermopile and switches connected to power a motor;

FIG. 19 shows control circuit 2 cycle for the electrical power generation system showing the electrical circuit including the batteries, capacitors, thermopile and switches connected to power a motor; and

FIG. 20 is a diagram of the entire power generating system of the present invention.

### DESCRIPTION OF THE PREFERRED EMBODIMENTS

The present invention is a thermoelectric device which generates relatively high voltages, between 110V and 900V or more using a thermopile, temperature differentials and the Seebeck coefficient of dissimilar materials assembled in a unique manner and in conjunction with controls and batteries to power devices such as an electric motor.

Based on the Seebeck effect, the production of a small voltage across the length of a wire due to a difference in temperature along that wire creating an electromotive force (emf). Heat is converted directly into electricity at the junction of different types of wire. Because the electron energy levels in each metal shifts differently and a voltage difference between the junctions creates an electrical current. The Seebeck coefficients generally vary as a function of temperature and depend strongly on the composition of the conductor.

This effect is most easily observed and applied with a junction of two dissimilar metals in contact, each metal producing a different Seebeck voltage along its length. This translates to a voltage between the two (separated) wire ends. Most, if not all, pairs of dissimilar metals will produce a measurable voltage when their junction is heated. Combinations of certain selected metals produce more voltage per degree of temperature than others.

The Seebeck effect is typically linear in that the voltage produced by a heated junction of two wires is directly proportional to the temperature. This means that the temperature of the metal wire junction can be determined by measuring the voltage produced and provides an electric method of temperature measurement.

A thermocouple 18 is an electrical device consisting of two dissimilar conductors forming electrical junctions at differing temperatures. A thermocouple produces a temperature dependent voltage as a result of the thermoelectric effect.

Thermocouples, however, can be built from heavy-gauge wire for low resistance, and connected in such a way so as to generate very high currents for purposes other than temperature measurement such as electric power generation. By connecting many thermocouples in series as shown in the figures, alternating hot and cold temperatures at every other junction, a device called a thermopile can be constructed to produce substantial amounts of voltage and current:

If a plurality of thermocouples are configured as a simple thermopile with left and right sets of junctions at the same temperature, the voltage at each junction will be equal and the opposing polarities would cancel to a final voltage of zero. However, if the left set of junctions are heated and the right set cooled, the voltage at each left junction is greater than each right junction resulting in a total output voltage equal to the sum of all junction pair differentials.

In a thermopile, a source of heat such as from combustion, a chemical reaction, radioactive substance decay, or solar heat, etc.) is applied to one set of junctions, while the other set is bonded to a heat sink of some sort cooling fluid such as a gas for example air, or liquid such as for example water. An example of power generated by such heat sources is in a device called a radioisotope thermoelectric generator (RTG) which is an electrical generator that uses a thermopile to convert heat released by the decay of a suitable radioactive material into electricity by the Seebeck effect. An RTG has no moving parts but uses the radioactive decay to heat up one side of the thermopile. The thermopile in turn generates DC power to energize circuitry used in a satellites, space probes and unmanned facilities such as a series of lighthouses.

The present invention includes the generation and storage of liquid nitrogen. Then, in the event of a power failure, the liquid nitrogen is used to generate a large temperature gradient for a large bank of thermopiles which in turn generate DC voltage and current which is then converted to AC voltage to drive motors and other critical loads.

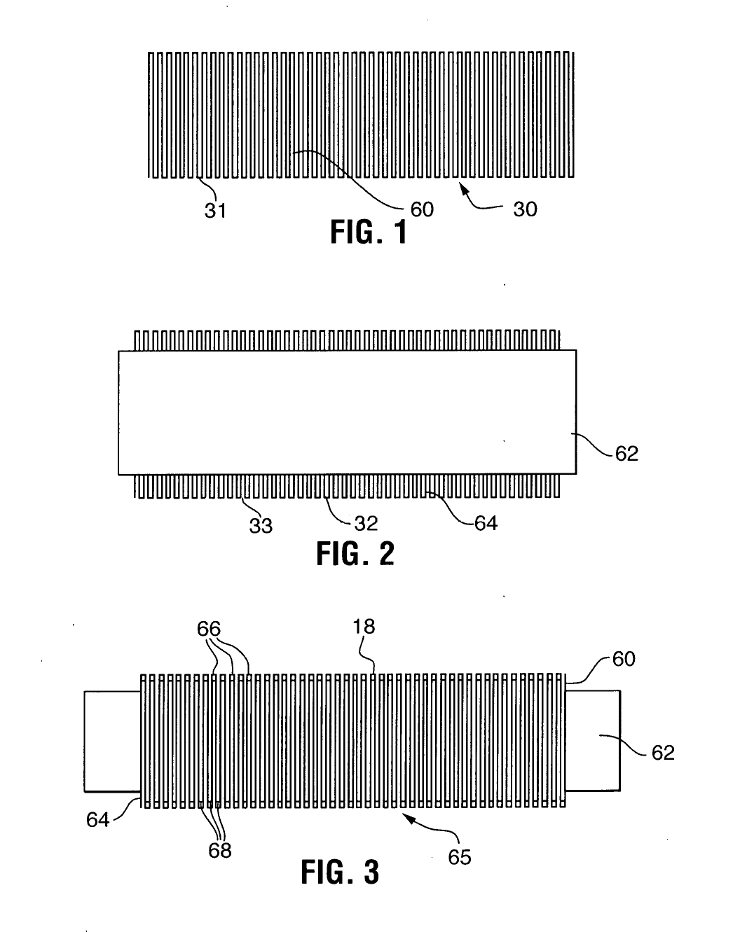

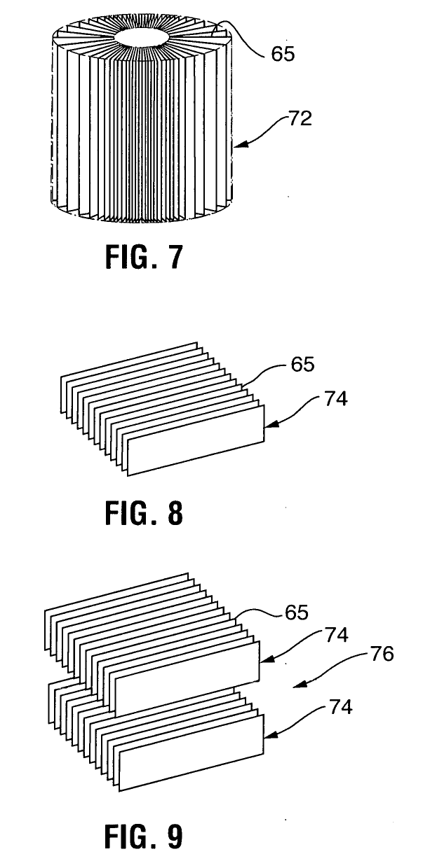

In accordance with the present invention, the FIGS. 1-19 illustrate an electrical power generation system 10 for driving a load such as a motor 24. Parts of the system 10 are recharged by incoming power 130 which is generally 110 VAC or 220 VAC. This powers a compressor 12 which is used in the generation of liquid nitrogen which is stored in a pressurized tank 16. The incoming power 130 also recharges 12 volt DC batteries 22 with a battery charger 26. When electrical power is required to drive motor 24, which may be a drive motor for an electric car or for a backup power scheme, the liquid nitrogen is used to cool the thermocouples on one side of a thermopile 39. The thermocouples on the opposite side of the thermopile 39 are at ambient temperature. The resulting temperature gradient of over 200° C. result in a large and useable DC output voltage. The voltage is dependent upon the size of the thermopile. Control circuitry 20 charges capacitors 42 using the 12 VDC batteries 22. The voltage on the capacitors is added to the voltage generated by the thermopile. Control circuitry takes this total voltage and inverts or changes the DC voltage to AC voltage and powers the motor 24.

The thermocouple 37 of the instant invention utilizes an electrical joining of two dissimilar such as copper and iron as shown in FIG. 16 or other dissimilar metals such as Nichrome and constantan, or combinations of others including but not limited to materials such as: silicon; bismuth and bismuth alloys and compounds; iron; copper; aluminum; germanium and germanium alloys; polycrystalline Bi₂Te₃—PbTe; antimony; gold; tantalum; lead and lead alloys; alumel; cromel; tungsten; molybdenum; platinum; tellurium and crystalline tellurium alloys and compounds; Ag—Pb—Sb—Te quaternary systems; Half-Heusler compounds; High-ZT oxides; skutterudite compounds and other materials with Seebeck coefficients sufficient to generate useful voltage and/or current and/or power.

As shown in FIG. 1 a zig-zag arrangement of a Nichrome sheet 30 of Nichrome wire 60 of a selected thickness, for example, 0.5 mm thick×100 mm wide×625 mm long. In an alternate embodiment the wire is 1.39 mm thick×100 mm wide and 400 mm long wherein the thickness of the wire and the gap there between are each about 3/16 of an inch in width. The wire and gap thickness is variable. The wire may also be formed or printed in a sheet wherein a strip of material remains between the end loops 31 of the wire 60 and the edge of the sheet 30.

As shown in FIG. 2, the second component comprising a constantan sheet 32 of constantan wire 64 can be formed as a 0.5 mm thick×100 mm wide×625 mm long zig-zag arrangement of constantan wire 64 which may be formed between the end loops 33 of the wire 64 and the edge of the sheet 32. The sheet 32 can be formed or configured having the same or similar dimensions of the Nichrome wire sheet 30 of FIG. 1.

A sheet of insulating material such as insulator card 62 is shown disposed in parallel alignment with either the sheet 30 or 32. The electrically insulating material comprising insulator sheet 62 is composed of MYLAR, polyethylene, styrene, paper, or other nonconducting material placed between the sheets of dissimilar electrically conductive materials, typically metals as shown in FIG. 3.

The dimensions of the sheets 30 and 36 of dissimilar metals can be altered to achieve different voltage results and meet different space requirements.

The insulating sheet 62 is approximately 50 mm wide which is more narrow than the width of the conductive sheets 30 and 32 so that a selected portion of each electrically conductive sheet 30, 32 containing electrically conductive wires 60 and 64 are in electrical communication with one another on either side of the insulating sheet 62. Furthermore, conductive sheets 30 and 32 are arranged on either side of the insulator sheet 62 so that the ends 31 of the loops of Nichrome wire 30 and the ends of the loops 33 of the constant=wire 64 are in alignment and the two components overlap each other.

Electrically conductive sheets 30 and 32 may be epoxied or otherwise chemically or mechanically affixed to insulating sheet 62. The wire ends 31 and 33, respectively of wires 60 and 64 are in contact with each other; on both sides of the assembly and fastened together by electrically conductive means as show in FIG. 3 form a thermocouple 18. The ends are soldered or welded together using a method such as electric resistance welding forming welds 66 and 68 on either side of insulator 62, but may also be mechanically crimped, or thermally fused, brazed, or soldered together. A plurality of alternating sheets of conductive sheet 30 and 32 may be disposed on insulating sheet 62 or they may also be deposited over each other creating an overlapping layered connection. They may also be connected via another conductive material such as wire.

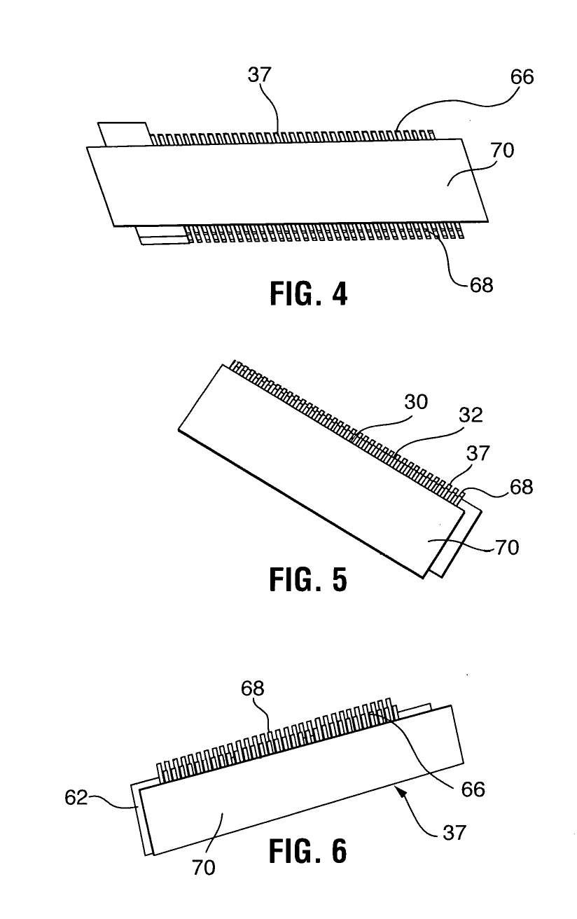

Conductive sheets 30, 32, and insulating sheet 62 together form a thermocouple subassembly 37 shown in the FIGS. 4, 5 and 6. Each connection of sheet 30 to sheet 32 forms one thermocouple assembly 37. Each “side” of the thermocouple assembly formed comprising sheet 30 or 32 is designated as an “element”. Multiple thermocouple assemblies 37 are thus connected in series forming a thermopile 39.

A plurality of thermocouple subassemblies 37 in electrical communication comprises a thermo-card 65. The thermo-card 65, when fully assembled can comprise a selected number of thermocouples, for example 200 thermocouples in a series. Multiple thermo-cards 65 are then connected in series with the last conductive element, for example, the constantan wire 60 of a selected thermo-card 65 electrically connected to the first Nichrome wire 60 of the adjacent thermo-card 65. The connections may be made by crimping the ends of a conductive wires to each of the elements and/or welding and or soldering/brazing the ends.

Therefore combining two thermo-cards 65 in series results in 400 thermocouples in series. Three thermo-cards 37 in a series results in 600 thermocouples in series and so on. In all, approximately 240 thermo-cards 37 are connected in series to create a thermopile 39 of 48,000 thermocouples in series.

The thermo-cards 65 may be arranged in a radial and cylindrical pattern 72 as shown in FIG. 7, or in a block form 74 as depicted in FIG. 8 or multiple block form 76 as shown in FIG. 9. The thermo-cards 65 may be fixed to one another in electrical communication by means such as epoxying them together with a polymer such as MASTER BOND cryogenic epoxy or other adhesives or bonding polymers. The block of thermo-cards 74 can then be encased in insulating material(s) such as polyurethane expanding foam, polystyrene expanded STYROFOAM, calcium silicate, sil-glas, silica-aerogel, sheep's wool, felt wool, rock wool or other insulating material.

Cryogenic liquid is used to create a large temperature differential across the thermo-cards 65. One preferred embodiment uses liquid nitrogen other low temperature fluids such as liquid helium, liquid oxygen, liquid hydrogen or other cryogenic liquids can be used as well.

Liquid nitrogen can be supplied by at least three different means. The cryogenic liquid could be supplied external to the system by purchasing or producing it by a separate system, and then the user adding it to a container such as a vacuum flask or other insulated container connected to the thermoelectric device system; the cryogenic liquid could be produced as a part of the thermoelectric device system; or a system using the Thomson-Joule expansion effect may be employed to create the cryogenic fluid.

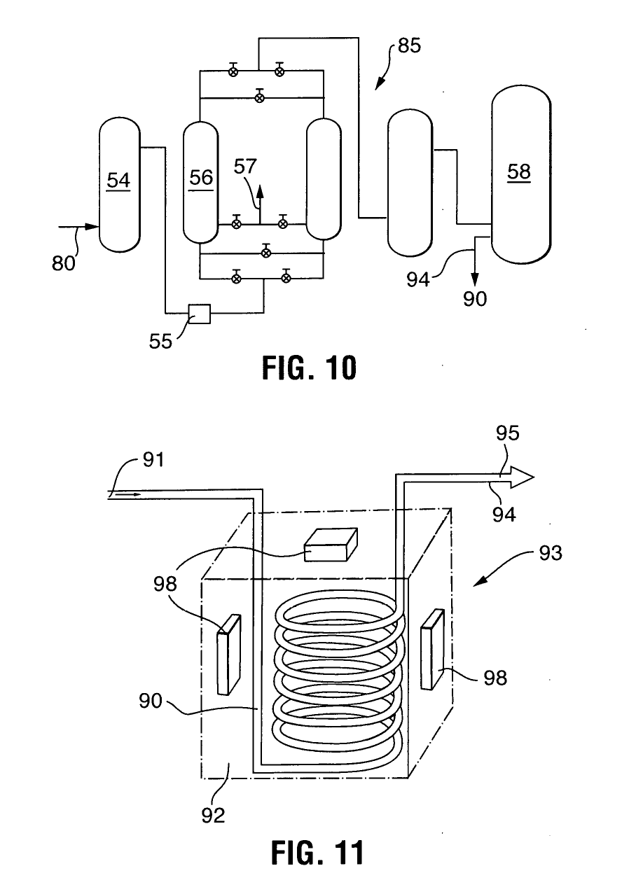

A system utilizing the Thomson-Joule expansion effect comprises the steps of forcing ambient air 80 through a filter 11 in line 51 after drying the air through a desiccant dryer 52. The air 80 would then be compressed to between approximately 3500 psi and 5000 psi using a SCUBA tank air compressor or other high pressure compressor 53. The compressed air would then be run through a pressure swing absorption system 85 as illustrated in FIG. 10 wherein the air is pumped to an air receiver 54 and then filtered through filter 55 before processing in a molecular sieve unit 56 utilizing Zeolite, or other oxygen entrapment material to separate out the nitrogen 90 portion of the air 80 and vent the oxygen through vent 57. The air stream containing the concentrated nitrogen 90 portion is pumped to a surge vessel 58.

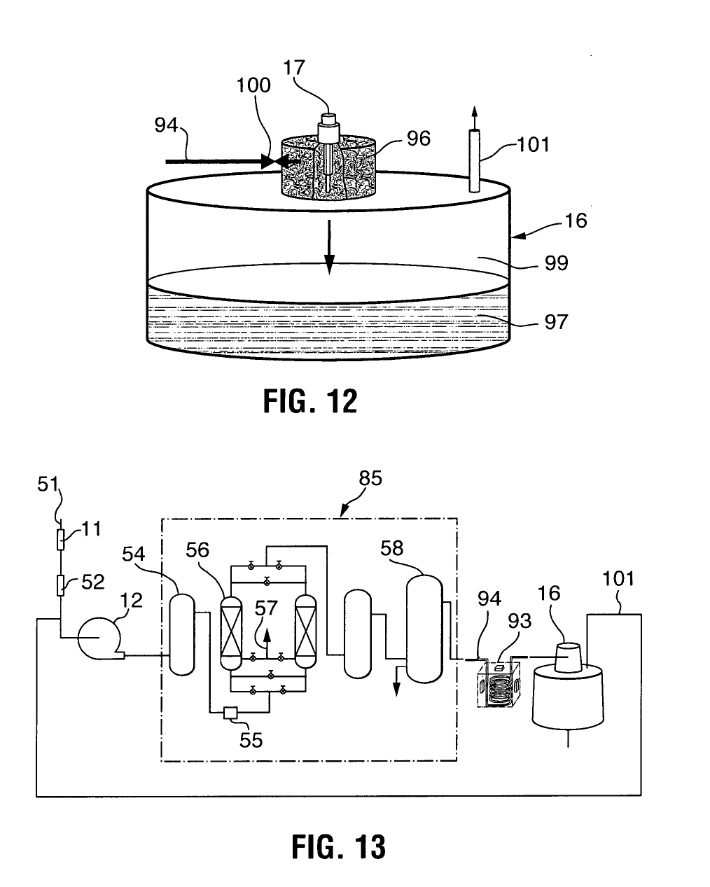

The air stream from the surge vessel 58 would then be 95% or higher concentrated, compressed nitrogen. The compressed nitrogen 90 would then flow from inlet 91 through a cooling bath system 93 as shown in FIG. 11, where a coolant 92 such as water or other coolant such as (water and propylene glycol) or (water and ethylene glycol) is cooled to near 0° C. and exits at outlet 94. The cooling bath may be brought to a low temperature such as 0° C. using Peltier coolers 98 attached to the outside of the bath container. The compressed nitrogen 95 is transferred through line 94 through an expansion valve and containment vessel as shown in FIG. 12.

The cooled compressed nitrogen gas 95 flows through tube or line 94 and through an expansion valve 100 and undergoes Thomson-Joule cooling/expansion. The compressed nitrogen tube 94 from the expansion valve 100 exits the valve and impinges on the cold head 17 of a Stirling Engine cryocooler. The Stirling Engine cryocooler can be purchased at Stirling Cryogenics and is described at the following link: http://www.stirlingcryogenics.com or at Janis Research Company at the following link: http://www.janis.com, model CH-202. The containment vessel 16 contains copper wool 96 to act as baffles. A portion of the expanded nitrogen gas, due to the Thomson-Joule effect, cools below the liquid temperature of nitrogen and the liquid nitrogen 97 falls into the bottom of the liquid nitrogen containment vessel. The portion of the nitrogen stream that remains a compressed nitrogen gas 99 is vented through transfer line 101 where in is recirculated to the inlet of the high pressure compressor 53 and the liquid nitrogen 97 from the containment vessel 16 is transferred to the thermopile 18.

The cold head 17 is surrounded by the copper wool 96 to act as a baffle and ensure proper resonance time on the cold surface. Nitrogen 97 that is liquefied drops to the bottom of the container and any nitrogen that remains as a nitrogen gas 99 is recirculated to the inlet line 101 of the compressor. The liquid nitrogen is contained in the containment vessel 16 until needed for the thermopile 18 in the thermoelectric generator system.

FIG. 13 illustrates the entire cryogenic system used to supply the cooling fluid to the thermopile 39 system utilizing the Thomson-Joule expansion effect pressure and swing absorption system 85 showing the air inlet, air filter 11, desiccant dryer 52, compressor 12, air receiver 54, pressure swing absorption system 85 with molecular sieve and surge vessel 58, coolant bath 93, containment vessel 16 with expansion valve 100, and liquid nitrogen flow to thermopile 39.

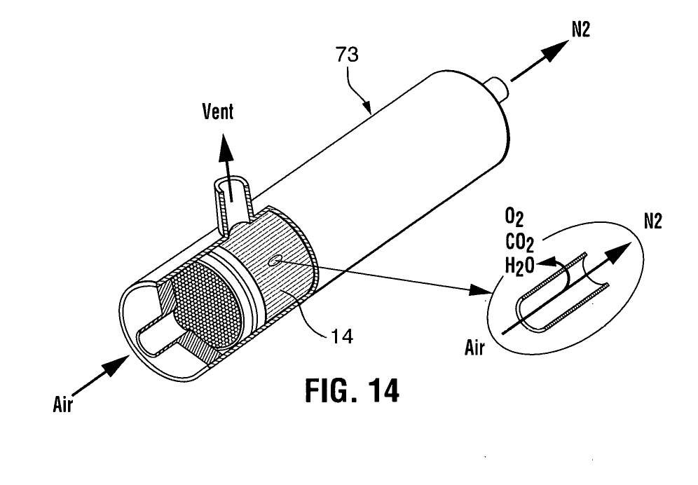

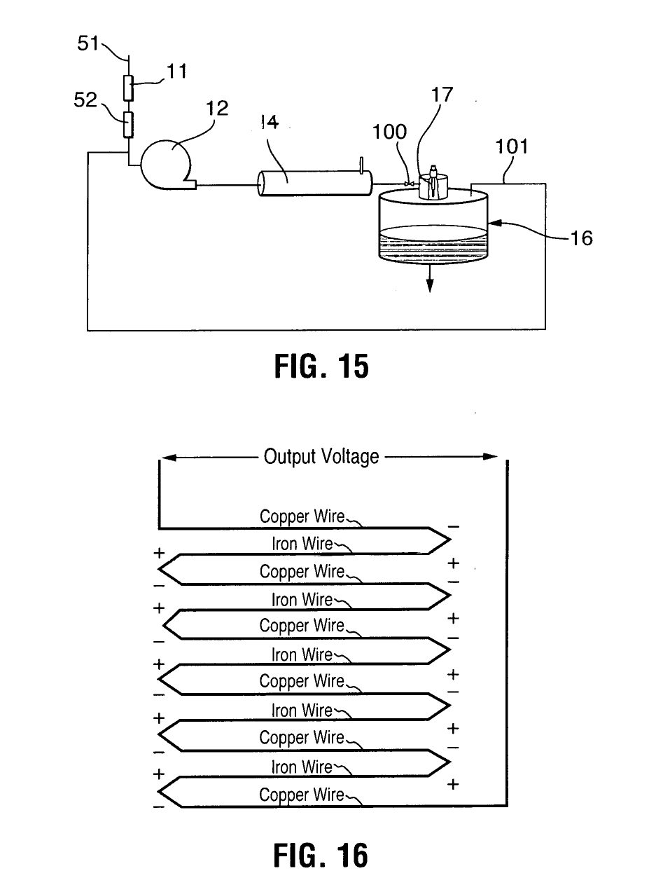

An alternate method for cryogenic liquid production is a gaseous diffusion process utilizing a thermoelectric device system 73 as best shown in FIGS. 14 and 15. Filtered air from filter 11 is dried through air filter 52 and compressed to approximately 175 psi via compressor 12. The compressed air flows through a nitrogen separation membrane unit 73, as shown in FIG. 14, for example, IGS Generon model 2-30-P1-HR includes a nitrogen separation membrane 4 which can be employed to separate oxygen, carbon dioxide and water from the nitrogen. As shown in FIG. 15, the compressed nitrogen enters an expansion valve 100 on a containment vessel 16. The nitrogen exits a flow tube and impinges on the Stirling Engine cryocooler cold head 17. A Stirling Engine cryocooler can be purchased at Stirling Cryogenics and is described at the following link: http://www.stirlingcryogenics.com or at Janis Research Company at the following link: http://www.janis.com, model CH-202. The compressed nitrogen from the a cold head 17 is surrounded by copper wool to act as a baffle and ensure proper resonance time on the cold surface to liquefy the nitrogen. Nitrogen that is liquefied drops to the bottom of the container 16 and any nitrogen that remains as a gas is recirculated through line 101 to the inlet of the compressor 12. The liquid nitrogen is then contained until needed in the thermoelectric generator system.

### Controls

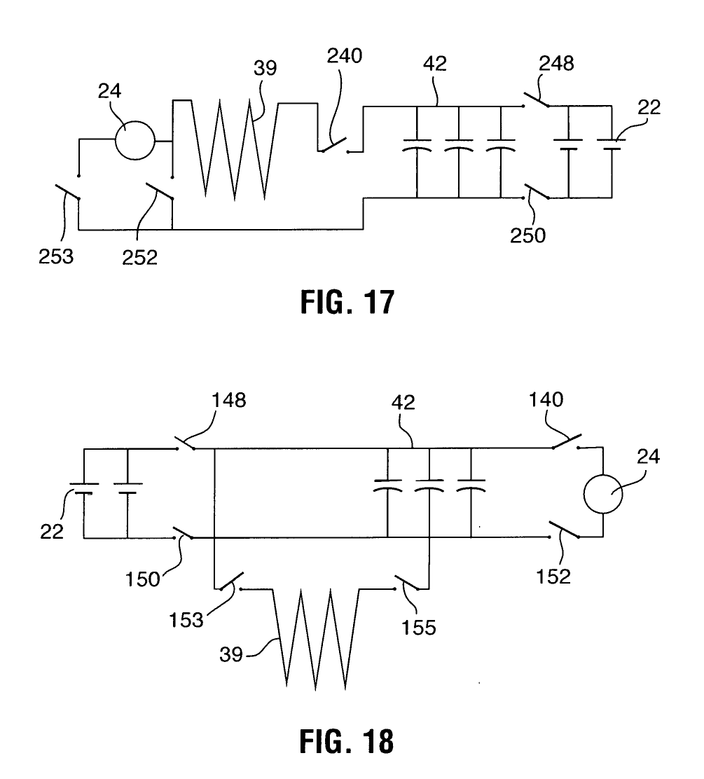

As shown in FIGS. 17-19, the voltage created by the thermopile 39 system must be controlled and augmented with external amperage to be useful. Batteries are employed to charge approximately five 1000 μF, 900 V capacitors 42 such as Cornell Dubilier Electronics (CDE) part number 947D102K901CJRSN. A diagram of the control circuit and its operating steps is shown in FIGS. 17-19. The cycling of the switches is described in the ‘Circuit Cycle tables as follows:

TABLE 1
Circuit 1 Cycle (FIG. 17)

| Cycle | | | | | | |
|---|---|---|---|---|---|---|
| Step | 240 | 252 | 248 | 250 | 253 | Action |
| Cycle | Open | Open | Open | Open | Open | All switches open - no current flow |
| Step 1 | | | | | | |
| Cycle | Open | Open | Closed | Closed | Open | Batteries put initial charge on capacitors |
| Step 2 | | | | | | |
| Cycle | Open | Open | Open | Open | Open | All switches open - no current flow |
| Step 3 | | | | | | |
| Cycle | Closed | Closed | Open | Open | Open | Thermopile brings capacitors up to high |
| Step 4 | | | | | | voltage |
| Cycle | Open | Open | Open | Open | Open | All switches open - no current flow |
| Step 5 | | | | | | |
| Cycle | Closed | Open | Open | Open | Closed | Capacitors discharge through the motor |
| Step 6 | | | | | | turning rotor |

TABLE 2
Circuit 2 Cycle (FIG. 18)

| Cycle | | | | | | | |
|---|---|---|---|---|---|---|---|
| Step | 140 | 152 | 148 | 150 | 153 | 155 | Action |
| Cycle | Open | Open | Open | Open | Open | Open | All switches open - no current flow |
| Step 1 | | | | | | | |
| Cycle | Open | Open | Closed | Closed | Open | Open | Batteries put initial charge on capacitors |
| Step 2 | | | | | | | |
| Cycle | Open | Open | Open | Open | Open | Open | All switches open - no current flow |
| Step 3 | | | | | | | |
| Cycle | Open | Open | Open | Open | Closed | Closed | Thermopile brings capacitors up to high |
| Step 4 | | | | | | | voltage |
| Cycle | Open | Open | Open | Open | Open | Open | All switches open - no current flow |
| Step 5 | | | | | | | |
| Cycle | Closed | Closed | Open | Open | Open | Open | Capacitors discharge through the motor |
| Step 6 | | | | | | | turning rotor |

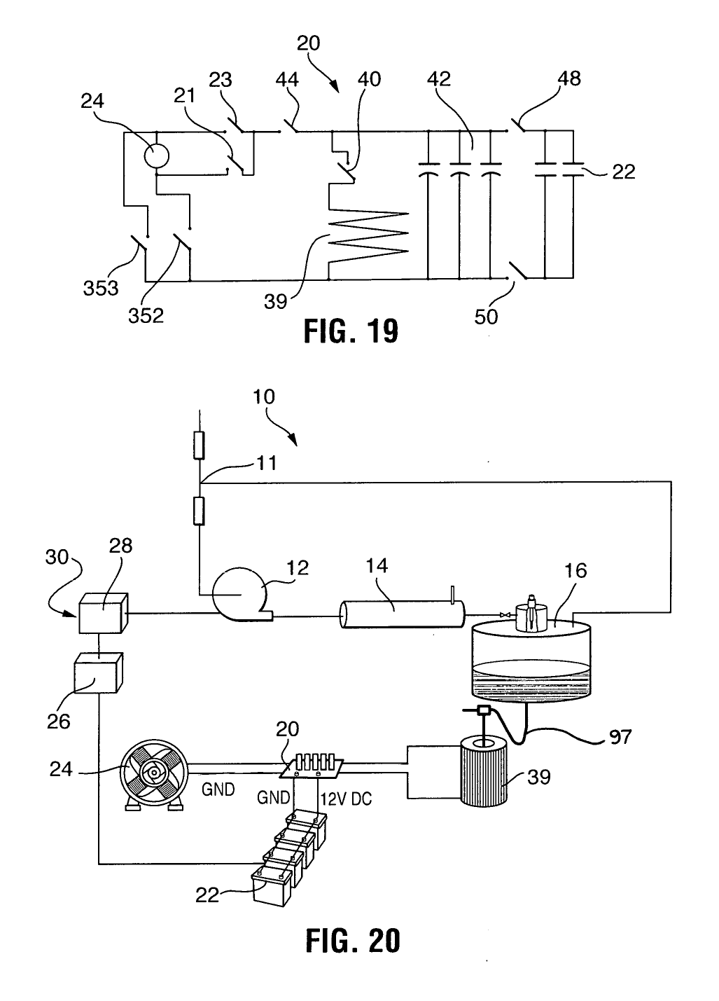

TABLE 3
Circuit 3 Cycle (FIG. 19)

| Cycle | | | | | (352 & 23) or | |
|---|---|---|---|---|---|---|
| Step | 40 | 44 | 48 | 50 | (353 and 21) | Action |
| Cycle | Open | Open | Open | Open | Open | All switches open - no current |
| Step 1 | | | | | | flow |
| Cycle | Open | Open | Closed | Closed | Open | Batteries put initial charge on |
| Step 2 | | | | | | capacitors |
| Cycle | Open | Open | Open | Open | Open | All switches open - no current |
| Step 3 | | | | | | flow |
| Cycle | Closed | Open | Open | Open | Open | Thermopile brings capacitors up |
| Step 4 | | | | | | to high voltage |
| Cycle | Open | Open | Open | Open | Open | All switches open - no current |
| Step 5 | | | | | | flow |
| Cycle | Open | Closed | Open | Open | Closed | Capacitors discharge through the |
| Step 6 | | | | | | motor turning rotor |

The switches may consist of high voltage fast-switching PNP power transistors such as ST Microelectronics model STN9360 operated via a microcontroller such as Microchip Technology model number PIC24FJ128GA006T-I/PT. The entire switching cycle can occur at different frequencies determined by a variable signal that alters the frequency by which the cycles occur, but primarily at a frequency to simulate single phase power supply as required.

### Operation

FIG. 19 illustrates an electrical power generation system 10 for driving a load such as a motor 24. When not in use the system 10 is plugged into and charged by an incoming power source 130 which is generally a 110 VAC or a 220 VAC source. This powers a compressor 12 which is used in the generation of liquid nitrogen which is stored in a pressurized containment tank 16. The incoming power source 130 also recharges 12 VDC batteries 22 with a battery charger 26. When electrical power is required to the drive motor 24, the liquid nitrogen is used to cool the thermocouples 18 on one side of a thermopile 39. The thermocouples on the opposite side of the thermopile 39 are at ambient temperature. The resulting temperature gradient or over 200° C. result in a large and useable DC output voltage. The voltage is dependent upon the size of the thermopile 39. Control circuitry charges capacitors 42 using the 12 VDC batteries 22. The voltage on the capacitors is added to the voltage generated by the thermopile. Control circuitry 20 takes this total voltage and inverts or changes the DC voltage to AC voltage and powers the motor 24.

When not in use, the system is plugged in to a standard 110 Vac or 220 Vac power plug connected to the power grid. During this phase, the system turns on a battery recharger and an air compressor. In the case of the system shown in FIG. 19, the system also operates a Stirling Cryocooler and control system. Regardless of the method, the air is converted into liquid nitrogen and contained in an insulated containment vessel until needed. At the same time, batteries on board the system are being recharged. During use, the unit is unplugged from the power grid. Liquid Nitrogen flows across one side of the thermocouples 18 in the thermopile 39 while the opposite edge is under atmospheric temperature. Thus a temperature gradient is created. Calculations are given below of the voltages, the number of thermocouples required and the subsequent number of thermos-cards required is given below for a temperature gradient of 220° C., the difference between the temperature of liquid nitrogen and average atmospheric temperatures:

| | | |
|---|---|---|
| | 575 | Voltage Required |
| | 220 | Temperature Delta Celsius |
| | | Material 1 Seebeck Coefficient |
| Nichrome | 25 | micro V/K |
| | | Material 2 Seebeck Coefficient |
| Constantan | −35 | micro V/K |
| | 43561 | Number of thermocouples Required |
| | 0.0625 | Thermocouple width (in) |
| | 25 | Length of each Thermopile Card (in) |
| | | Total Length of Thermopile 138.306 |
| | 5445 | (in) 2 m |
| | | Number of Thermopile Cards |
| | 218 | Required |
| | 1.65137 | angle per card in degrees |
| | 61 | when arranged as in figure |
| | 200 | Thermocouples per card |
| | 43561 | Total number of Thermocouples |

As shown in Table 3 showing Circuit 3 and in FIG. 19, the selected size, material property, and physical properties creates 575 volts DC. The voltage is supplied to the control unit described above. As the control system cycles, large capacitors 42 are initially charged by batteries 22 to 12V. The batteries 22 are disconnected from the capacitors 42 by opening switches 48 and 50. The capacitors 42 are connected to the thermopile 39 by switches 40 and 44 and brought up to 575V by the voltage from the thermopile 39. The capacitors 42 are disconnected from the thermopile 39 by opening switch 44. The capacitors 42 are then connected to a 575 VAC motor 24 by closing switches 352 and 23 for the positive half cycle or by closing switches 353 and 21 for the negative half cycle. Cycle 3 is performed 120 times per second with switches 352 and 23 being closed in step 6 of every odd numbered cycle and switches 353 and 21 being closed in step 6 of every even numbered cycle. The closing of switches 352 and 23 places positive DC voltage at the top motor lead, and the closing of switches 353 and 21 places positive DC voltage at the bottom motor lead approximating a sine wave across the motor windings as cycle 3 is performed. As the capacitors 42 are discharged across the windings, the armature is excited and the motor turns. The frequency with which the cycle is performed and the duty cycle for switches 352, 23, 353 and 21 determine the speed of the motor.

The electrical power generating system comprises the following steps. Liquid nitrogen is generated and stored for providing a large temperature gradient to a thermopile by applying the liquid nitrogen to one side of the thermopile and ambient air an opposite side of the thermopile which is connected to an output of the thermopile and to the control circuit high current switching transistors. A group of rechargeable batteries is connected to the control circuit through high current switching transistors which are connected to a parallel grouping of large power capacitors to a control circuit through high current switching transistors. A control circuit is connected to a winding of a motor through high current transistors capable of switching large currents in a range of hundreds of amps at voltages in a range of hundreds of volts. The control circuit causes a switching cycle to occur in the range of 0-120 times per second with a selected duty cycle.

The switching cycle comprises the following steps: a) switching the batteries across the capacitors to charge the capacitors up to the battery voltage; b) opening connection from the batteries to the capacitors; c) switching the thermopile across the capacitors to charge the capacitors to a required DC voltage; d) opening the connection between the thermopile and the capacitors; e) switching the capacitors across a motor winding with a first polarity; f) repeating steps a-d; g) switching the capacitors across the motor winding with an opposite polarity; and h) going to step a. for operation at 60 Hz, the above cycle is performed 60 times per second.

The amount of time per cycle that the motor winding is energized should be commensurate with the speed of the motor and therefore the drive frequency of the system. In other words, a higher motor speed requires not only a higher frequency but a higher current. Another embodiment of the present invention only includes charging of the capacitors in the event that the present voltage across the capacitors is equal to or less than the battery voltage.

Since one coulomb per second is equal to an amp, 115 amps is effectively supplied to the motor—sufficient to run 60 hp, 575 VAC motor. Other capacitor sizes, thermopile sizes, frequencies and battery voltages may be used to supply more or less voltage or amperage to operate alternative motor sizes. The motor speed is determined by the frequency of that the control unit cycles the operation. This is the circuit and operation for single phase power to a single phase motor. A similar but more complex arrangement of controls and switches can be connected to generate three phase power as required.

After use or when idle, the system is again connected to 110 Vac or 220 Vac external power to replenish liquid nitrogen and recharge batteries. The primary benefit of the system is to lessen the amperage supplied by the batteries. By using the high voltage of the thermopile, a high voltage motor can be used. Since Power=Voltage×Current, using a higher voltage motor requires less amperage. A 60 hp, 220 Vac electric motor requires 300 amps. A 60 hp, 575 Vac electric motor requires 115 amps. Thus, less amperage is required from the batteries because the current, in the range of milliamps, is stored in capacitors. The capacitors are brought up to high voltage by the thermopile. Thus, less batteries are required and battery life is greatly extended. Extending battery life would, therefore, extend the usable range of electric vehicles and other devices between recharging periods.

Other benefits include the fact that electric motors and solid state systems are inherently more reliable and longer lasting than conventional internal combustion power systems. There are less moving parts, less control and monitoring systems and emissions controls to fail in a purely electric system. The system is inherently suited to space systems and general aerospace systems since no oxygen combustion is required and the weight of fuel and combustion systems is avoided.

The electrically conductive sheets 30 and 32 may also be made by laser cutting or mechanically milling the wire arrangements to shape. The shapes may also be made chemically milling the sheets in a photo resist and exposure or by screen printing the hole pattern on the sheet and a subsequent chemical etch process similar to etching of printed circuit boards. The shapes may also be created by laying the Nichrome and constantan on a substrate similar to printing. Semiconductor and/or other polycrystalline materials such as bismuth and silicon may be used by utilizing a process of growing crystals or otherwise leaving a coating of the material on a substrate similar to methods used in semiconductor manufacture.

It is anticipated that liquid nitrogen can made as a part of the system or supplied, commercially and/or externally. If supplied external to the system, it can be added to the containment vessel similar to adding gasoline to an automobile.

The foregoing detailed description is given primarily for clearness of understanding and no unnecessary limitations are to be understood therefrom, for modification will become obvious to those skilled in the art upon reading this disclosure and may be made without departing from the spirit of the invention and scope of the appended claims. Accordingly, this invention is not intended to be limited by the specific exemplification presented herein above. Rather, what is intended to be covered is within the spirit and scope of the appended claims.

I claim:

1. A thermo-electric device for generating power comprising:
a liquid nitrogen generating and storage system connected to a control circuit through high current switching transistors;
a large thermopile whose temperature gradient is provided by the liquid nitrogen and ambient air, said temperature gradient causing said thermopile to generate a large DC voltage at two output terminals, thus supplying said large DC voltage to said control circuit;
a group of rechargeable batteries connected to said control circuit through high current switching transistors;
a parallel grouping of large power capacitors capable of operating in a range of hundreds of volts DC connected to said control circuit through high current switching transistors; and
said control circuit including said high current switching transistors capable of switching large currents in a range of hundreds of amps at voltages in a range of hundreds of volts, said circuit connecting said batteries to said grouping of capacitors through selected ones of said switching transistors, said circuit connecting said thermopile to said grouping of capacitors through selected ones of said switching transistors, and said circuit connecting a winding of a motor to said grouping of capacitors through selected ones said switching transistors by either of two possible polarities.

2. A method for generating power with a thermo-electric device, comprising the steps of:
generating and storing liquid nitrogen;
providing a large temperature gradient to a thermopile by applying said liquid nitrogen to one side of said thermopile and ambient air an opposite side of said thermopile and connecting an output of said thermopile to said control circuit high current switching transistors;
connecting a group of rechargeable batteries to a control circuit through high current switching transistors;
connecting a parallel grouping of large power capacitors to a control circuit through high current switching transistors; and
connecting a control circuit to a winding of a motor through high current transistors capable of switching large currents in a range of hundreds of amps at voltages in a range of hundreds of volts, said control circuit causing a switching cycle to occur in the range of 0-120 times per second with a selected duty cycle, said switching cycle comprising the following steps:
a. switching said batteries across said capacitors to charge said capacitors up to said battery voltage;
b. opening connection from said batteries to said capacitors;
c. switching said thermopile across the capacitors to charge the capacitors to a required DC voltage;
d. opening said connection between said thermopile and said capacitors;
e. switching said capacitors across a motor winding with a first polarity;
f. repeating steps a-d;
g. switching said capacitors across said motor winding with an opposite polarity; and
h. going to step a.

3. A thermo-electric device for generating power comprising:
a liquid nitrogen generating and storage system;
a control circuit connecting to said liquid nitrogen generating system through high a plurality of current switching transistors;
a thermopile having a temperature gradient generated between a liquid nitrogen gradient and an ambient air gradient, said thermopile generating a DC voltage an output terminal, said DC voltage supplying a control circuit;
a plurality of rechargeable batteries connecting to said control circuit through a high current switching transistors;
a plurality of power capacitors capable of operating in a range of hundreds of volts DC connecting to said control circuit through said high current switching transistor;
said control circuit including at least one high current switching transistor capable of switching currents at a selected amp at a selected voltage;
said circuit connecting said plurality of batteries to said plurality of capacitors through said selected switching transistors;
said control circuit connecting said thermopile to said plurality of capacitors through selected switching transistors and said control circuit connecting a winding of a motor to said plurality of capacitors through said high current switching transistors by either of two possible polarities providing a positive and a negative half cycles of a quasi sinusoidal power signal.

4. The thermo-electric device of claim 3 wherein said thermopile comprises:
a first sheet of conductive material;
a second sheet of conductive material having a Seeback Coefficient compatible with said first sheet of conductive material;
said first sheet and said second sheet are clad to a high dielectric substrate and thermocouple lines are formed etched or printed onto said dielectric substrate forming a thermopile card;
said thermopile card is wired in series with at least one other thermopile card forming a thermopile block.

5. The thermo-electric device of claim 4 wherein said thermocouple lines are formed onto said dielectric substrate by etching or printing.
